(19) United States
(12) Patent Application Publication
(10) Pub. No.: US 2026/0086157 A1
(43) Pub. Date: Mar. 26, 2026

(54) Transformer-Based Time-Series Algorithms for Battery Health Analysis and Related Methods, Software, and Systems

(71) Applicant: SES Holdings Pte. Ltd., Singapore (SG)

(72) Inventors: Shaoxiong Hu, Shanghai (CN); Mengdi Zhou, Shanghai (CN); Weijie Mai, Shanghai (CN)

(21) Appl. No.: 19/336,830

(22) Filed: Sep. 23, 2025

Related U.S. Application Data
(60) Provisional application No. 63/698,926, filed on Sep. 25, 2024.

(51) Int. Cl. G01R 31/367; G01R 31/388; G01R 31/392; G06N 3/045

(52) U.S. Cl. CPC G01R 31/367; G01R 31/388; G01R 31/392; G06N 3/045

(57) ABSTRACT

Methods of analyzing battery health using deep-learning models based on transformer architecture. The methods can be used to determine, for example, battery state of charge (SOC), state of health (SOH), or remaining useful life (RUL), or any combination thereof. In some embodiments, portions of multivariate battery data, such as capacity, energy, time, temperature, voltage, current, etc., input into a model of the present disclosure are randomly masked and subsequently reconstructed by the model to learn contextual information and multivariate interaction. In some embodiments, the model employs self-attention mechanisms to train without explicit labeled data and estimated SOC, SOH, and/or RUL. In some embodiments, the model is applied to various downstream tasks like anomaly detection, SOX estimation, and/or RUL prediction, among others, using a flexible adaptor that is independent of the pretrained model. Related software and systems are also disclosed.

### RELATED APPLICATION DATA

This application claims the benefit of priority of U.S. Provisional Ser. No. 63/698,926, filed Sep. 25, 2024, and titled “TRANSFORMER-BASED TIME-SERIES ALGORITHMS FOR BATTERY HEALTH ANALYSIS AND RELATED METHODS, SOFTWARE, AND SYSTEMS”, which is incorporated by reference herein in its entirety.

### FIELD

The present disclosure generally relates to the field of battery monitoring and safety. In particular, the present disclosure is directed to transformer-based time-series algorithms for battery health analysis and related methods, software, and systems.

### BACKGROUND

Safety in battery cell testing is critical for both test personnel and equipment. Safety of test personnel and equipment can become compromised in the event of a battery malfunction, so battery health must be carefully monitored. However, for battery cells having different designs and testing conditions, traditional models struggle to develop a unified model framework for different tasks. One model that works well for one battery type may not work for a different battery type, and one model that works well in a certain condition may not work in a different condition. User behaviors are also very different from person to person and hard to predict. Moreover, it is very challenging to learn battery health in terms of both long and short periods (e.g., years and days) in a single model. As a result, the precise labels for SOC (State of Charge), SOH (State of Health), and RUL (Remaining Useful Life) are difficult to obtain in real-world scenarios using a unified model.

Time-series analysis is crucial in various domains for understanding and predicting sequential data and has been used in connection with analyzing battery health. Traditional methods often rely on statistical models or machine-learning techniques that require extensive labeled data and feature engineering. The transformer-type deep-learning architecture, originally designed for natural language processing, has shown promise in handling sequential data due to its self-attention mechanism, which allows it to capture long-range dependencies. However, applying such transformers to time-series data, especially in the context of battery health monitoring, presents unique challenges that necessitate novel approaches to model training and application.

### SUMMARY

In one implementation, the present disclosure is directed to a computer-implemented method of analyzing battery data to assess health of a battery. The method includes training an artificial intelligence (AI) model using a plurality of multivariate time-series data sets from battery cycling tests, wherein the AI model has a transformer architecture; and applying the AI model to the battery data so as to assess the health of the battery.

In another implementation, the present disclosure is directed to a computer-implemented method of assessing health of a battery. The method includes receiving measured battery data regarding the battery; inputting the measured battery data into a transformer-based battery-health model that has been trained on historical battery testing data; and receiving an indication of the health of the battery as an output of the battery-health model.

In still another implementation, the present disclosure is directed to a machine-readable storage medium containing machine-executable instructions for performing either or both of the methods described immediately above.

In yet another implementation, the present disclosure is directed to a system, which includes at least one processor for executing machine-executable instructions; and a machine-readable storage medium operatively connected to the at least one processor, wherein the machine-readable storage medium containing machine-executable instructions for performing either or both of the methods described above.

### BRIEF DESCRIPTION OF THE DRAWINGS

For the purpose of illustration, the drawings show aspects of one or more embodiments of the present disclosure. However, it should be understood that the present disclosure is not limited to the precise arrangements and instrumentalities shown in the drawings, wherein:

FIG. 1 is a diagram illustrating an example deep-learning model of the present disclosure deployed in a battery-analysis scenario;

FIG. 2A is a representation of a data sequence of an example battery-analysis scenario applied to a Type 1 version of the deep-learning model of FIG. 1;

FIG. 2B is a representation of a data sequence of an example battery-analysis scenario applied to a Type 2 version of the deep-learning model of FIG. 1;

FIG. 3 is a diagram illustrating an example representation-based process for battery anomaly detection and/or remaining useful life prediction; and

FIG. 4 is a diagram illustrating an example finetunable model that includes a deep-learning model and flexible adaptor that provides for finetuning of the finetunable model to increase model performance for one or more particular tasks.

### DETAILED DESCRIPTION

### General

In some aspects, the present disclosure is directed to computer-implemented methods that are provided for analyzing time-series battery data using a deep-learning model based on a transformer-type architecture, referred to hereinafter as a “transformer” or “transformer architecture”. In some embodiments, each method includes training a deep-learning model, or simply “model” herein, with multivariate time-series data from battery cycling tests, which encompass various parameters such as capacity, energy, time, temperature, voltage, current, and/or others in any suitable combination. In some embodiments, during pretraining, portions of the data are randomly masked and subsequently reconstructed by the model to learn contextual information and multivariate interactions. In some embodiments, the model employs self-attention mechanisms to train without explicit labeled data and estimates the battery's state of charge (SOC), state of health (SOH) (SOC and SOH collectively referred to herein as “SOX”), and remaining useful life (RUL). In some embodiments, the model is applied to various downstream tasks like anomaly detection, SOX estimation, and/or RUL prediction, among others, using a flexible adaptor that is independent of the pretrained model. For specific tasks, the model is finetuned by masking the input with a specific mechanism and adjusting only the last few blocks, keeping the core transformer layers unchanged. In an example, a foundation model having about 10 million parameters and trained on a dataset comprising about 10 years of battery testing data, is operated on a graphics-processing-unit (GPU)-equipped computational system to manage the high computational cost. In other embodiments, differing numbers of parameters and data-set sizes can be used, and the model may be operated in a GPU-equipped computational system or one or more other suitable computing environments. Additionally, the example trained model supports zero-shot applications by setting appropriate masks for the input, enabling direct use for tasks such as anomaly detection, SOX estimation, and RUL predictions.

The methods disclosed herein may be implemented in various systems, such as a battery testing system and/or a battery management system (BMS). For example, in some embodiments, computer-implemented methods of assessing health of a battery are implemented in a BMS. The computer-implemented methods of assessing health of a battery may comprise receiving measured battery data regarding the battery; inputting the measured battery data into a transformer-based battery-health model that has been trained on historical battery testing data and then receiving an indication of the heath of the battery as an output of the battery-health model. In some embodiments, the transformer-based battery-health model may be trained in accordance with any of the methods for training the model disclosed herein or apparent therefrom. In some embodiments, the BMS includes sensors for measuring battery data and circuitry for operating the sensors and/or collecting data from the sensors. In some embodiments, the BMS includes a monitor, and the output of the battery-health model is displayed to a user on the monitor using suitable imaging software. Those skilled in the art will readily understand how to design and implement a useful BMS using only information known in the art and this disclosure as a guide for the transformer modeling implemented in the BMS.

The methods disclosed herein may be executed in software. For example, in some embodiments, a machine-readable storage medium contains machine-executable instructions for performing one or more of the methods disclosed herein. The term “machine-readable storage medium” includes a single hardware memory of any suitable known type, such as, for example, RAM, ROM, cache memory, solid-state memory, magnetic memory, and optical memory, among others, as well as multiple hardware memories of the same or differing types that each store all or a portion of the relevant machine-executable instructions. As used herein, “machine-readable storage medium” does not include transitory signals, such as signals in which data is encoded onto a carrier wave or is encoded into pulsed signals.

As noted above, in some embodiments computer-implemented methods for analyzing battery data employ models based on transformer architecture. In a preferred embodiment, the transformer is a bidirectional-type transformer and is encoder-only. In other embodiments, a decoder with an autoregressive transformer may be added. The architecture of the model is similar to encoder-only large language models (LLMs). Those skilled in the art will readily understand the types and configurations of models that can be used for the data sequences/time-series data at issue.

At a high level, in some embodiments, a method of analyzing battery data includes training the model with multivariate time-series data sets. In some embodiments, a method of analyzing battery data includes applying the model for analyzing health of a battery. In some embodiments, a method of analyzing battery data includes both training the model with multivariate time-series data sets and then applying the model for analyzing health of a battery. In embodiments wherein a model is applied, the model can be applied in one or more of at least two general ways: (a) zero-shot applications and (b) finetuning. In embodiments wherein a model is finetuned, finetuning can be done in one or more of at least three general ways: (i) finetuning the model, (ii) finetuning a small part of a module in the larger model, and (iii) finetuning using a flexible adaptor independent of the model. A model of the present disclosure has powerful representation capabilities, enabling it to learn causal relationships between various features during battery operation. By accurately estimating a battery's SOC, SOH, and RUL, a current health status of the battery can be evaluated even with limited available data, which improves the cold-start problems from prior methods significantly. A model of the present disclosure can be configured to also have strong transferability, making it suitable for differing types of batteries and/or differing usage conditions. One pretrained model may be used for differing batteries and/or differing usage situations with finetuning, while traditional solutions only work in a very specific task and need new models if a sense did not exist before. The model architecture also allows a combination of current and potential future information, rather than only making use of historic information.

### DETAILED EXAMPLES

### Model Training

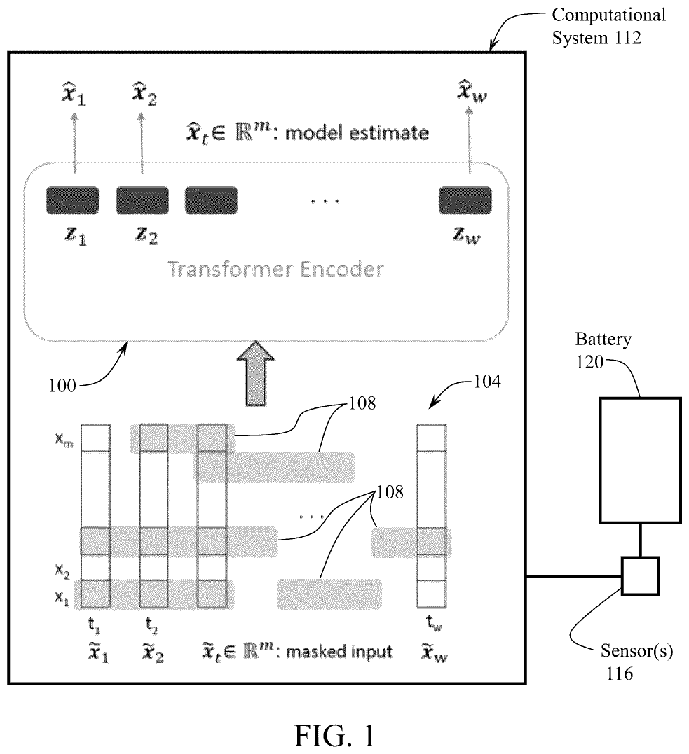

Referring to FIG. 1, in an example embodiment, a method of the present disclosure includes training a model 100, here, a transformer encoder, with multivariate time-series (MTS) data 104 from battery cycling tests, which encompasses various parameters such as, for example, capacity, energy, time, temperature, voltage, current, and/or other parameters. In the MTS data 104 of FIG. 1, x₁ through xₘ indicate the differing parameters and t₁ through t_{w} represent the differing sample times. During pretraining, as shown in FIG. 1, portions of the MTS data 104 (such as parameters measured at certain time-series snippets, like steps, phases, cycles, etc.) are randomly masked, as represented by masks 108 (only some labeled) at differing locations within the MTS data, and the model 100 is used to reconstruct this masked information, thereby learning contextual information and multivariate interactions within the MTS data. The model 100 utilizes self-attention mechanisms within the transformer to train without explicit labeled data. In FIG. 1, \tilde{X}ₜ are the masked input parameter vectors, \hat{X}ₜ are the transformed versions of \tilde{X}ₜ, and Zₜ denote the encoder's contextual embeddings.

In this example, the model 100 learns contextual information of the MTS data 104, as well as multivariate interactions during the pretraining process. For example, the model 100 may learn how current interacts with voltage. Because the model 100 learns contextual information and multivariate interactions, it does not require explicit labels (e.g., for SOX, normal or not normal) as many prior-art models do, which is a valuable time-saver. The model 100 learns internal representations of the MTS data 104 itself. In some embodiments, the model 100 is trained on a largescale mixture of long and short MTS data 104 based on the transformer architecture that can be applied in various scenarios instead of training from scratch for a new case. In one implementation of the model 100, ten years of lithium-metal battery testing data was used for training a single large model, and it took around 10 days for the training process with an Nvidia A100 GPU (available from Nvidia Corporation, Santa Clara, California) and around 18M of data with a total 10 million parameters.

In some embodiments, the model 100 is operated on a computational system 112, such as, for example, a computational system equipped with multiple GPUs to handle the large computational cost required by performance. While not illustrated for the sake of simplicity, those skilled in the art will readily understand that the computational system 112 will include all components necessary for the model to function. When powerful GPUs are needed and as those skilled in the art will readily understand, the model 100 may be deployed on a cloud server (not shown) while uploading MTS data 104 from one or more sensors 116 in operative communication with a battery 120, which can be or comprise a single battery cell or be or comprise multiple battery cells and be of any battery form, such as a battery pack or battery module, among others.

### II. Applying the Model

In some instantiations, after the model 100 is trained, it is used to estimate the SOC, SOH, and/or RUL of the battery 120 and can be applied to various downstream tasks, including anomaly detection and life prediction. For example, the model 100 can be applied in at least two general ways: (a) zero-shot applications and/or (b) finetuning.

### II. A. Zero-Shot

Once finished training, in some embodiments, the model 100 can be used for zero-shot learning, meaning that the output of the model 100 is applied to downstream tasks by feeding relevant inputs while not changing the model itself and not having learned on labeled data. Applying the model 100 to zero-shot learning does not require any further modification. The model may directly be used for anomaly detection, SOX estimation, and RUL predictions by setting appropriate masks for the input.

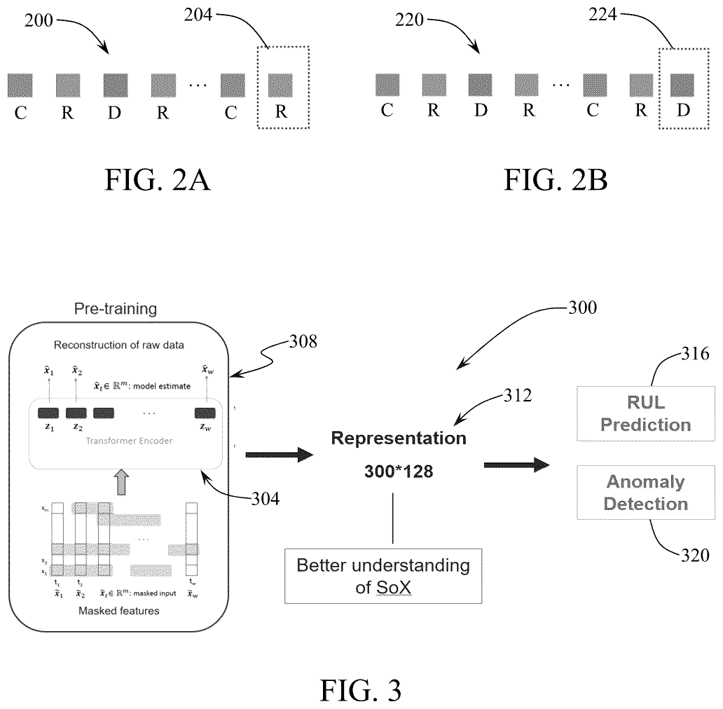

For example, in FIGS. 2A and 2B, only the feature(s) (e.g., voltage, discharge energy, discharge capacity, etc.) at time T that is sought to be estimated is masked, and the historic information from 1 to T-1 and other features at time T are kept open. The model 100 (FIG. 1) will make use of the historic time series along with the current conditions at time T to estimate the target at time T.

More particularly, FIG. 2A represents a sequence 200 of charging, resting, and discharging phases (C, R, and D respectively in FIG. 2A) of a battery, such as the battery 120 of FIG. 1, in the context of using a Type 1 encoder version of a model of the present disclosure, such as the model 100 of FIG. 1. In this context, “Type 1” indicates the task of SOC estimation. In the example of FIG. 2A, the Type 1 encoder (˜9k) is used for estimating the end voltage at the last rest phase (R) indicated at 204. In this example, the Type 1 encoder operates on the MTS data 104 with the end voltage in the last rest phase (R) 204 masked to estimate the voltage at that rest phase.

FIG. 2B represents another sequence 220 of charging, resting, and discharging phases (C, R, and D respectively in FIG. 2B) of a battery, such as the battery 120 of FIG. 1, in the context of using a Type 2 encoder version of a model of the present disclosure, such as the model 100 of FIG. 1. In this context, “Type 2” indicates the task of SOH estimation. In the example of FIG. 2B, the Type 2 encoder (˜3k) is used for estimating the discharge capacity at the last discharge phase (D) indicated at 224. In this example, the Type 2 encoder operates on the MTS data 104 with each of the end voltage, discharge energy, and discharge capacity in the discharge phase (D) 214 following the last rest phase (R) masked to estimate the discharge capacity at that discharge phase.

In some embodiments, such as for anomaly detection and RUL prediction, no MTS data is masked after pretraining, but rather representations are used. FIG. 3 illustrates such a representation-based process 300. In FIG. 3, a model 304 is or has been pretrained, such as at pretraining block 308, and one or more representation(s) 312 are generated. The pretraining at pretraining block 308 may be the same as or similar to the pretraining illustrated in FIG. 1 and described above. As used herein, a representation, such as each representation 312 of FIG. 3, is a multi-dimensional vector that is an output of a final hidden layer (not shown) of the model 304. In the final hidden layer, the model projects data into higher dimensional space. In the example of FIG. 3, each representation 312 is a multi-dimensional vector having a length of 300 pieces of MTS data and 128 dimensions representing 128 different aspects of the model 304. As those skilled in the art will readily appreciate, since the model 304 is a battery expert after being trained on MTS data from battery testing and/or battery monitoring, it gives more powerful data representations 312 by feeding target time series directly into the pretrained model 304. These more powerful representations 312 can provide, for example, a better understanding of SOX. Then, the generated representations 312 can be used, for example, as augmented features to train smaller models, such as a RUL-prediction model 316 for RUL prediction and/or an anomaly-detection model 320 for anomaly detection. Representations 312 are regarded as powerful features for training additional smaller models, such as the RUL-prediction and anomaly-detection models 316 and 320, respectively.

### II. B. Finetuning for Downstream Tasks

In other embodiments, once finished pretraining, a model of the present disclosure, such as model 100 or model 304, may be finetuned. Finetuning involves transferring learning by training parameters of the pretrained model on new data. Finetuning can be done on the model, on a small part of a module of the model, or with a flexible adapter independent of the model.

### II. B.i. Finetuning a Module of the Model

For example, a pretrained model, such as either of the models 100 and 304 of FIGS. 1 and 3, respectively, can be finetuned for multiple downstream tasks, such as anomaly detection, SOX estimation, life prediction, etc. In an example, the input MTS data is masked by a specific mechanism instead of randomly done in the pretraining stage. In other words, a specific target is known and masking is directly related to that target. In this embodiment, only the last few blocks of the pretrained model need to be adjusted for specific tasks. The core part (transformer layers), which contains the AI understanding of battery data, remains unchanged. In other words, the blocks that are not being finetuned are frozen. For example, if a goal is to estimate the SOC of a battery, only the balanced voltage needs to be estimated. Only the relevant voltage would need to be masked, and all other features would be left unmasked, as in the figure below. The model will learn to estimate the balanced voltage for the SOC target by training on only a small party of modules in the large model. This makes the model adapt to the new task and save time and expense from avoiding training a new model from scratch.

Being a battery data expert, the model would need much less labeled data (e.g., SOX, normal or not normal) to adapt a pretrained model to specific tasks, which is a bottleneck for traditional machine learning/deep learning methods.

### II. B. ii. Finetuning Using a Flexible Adaptor

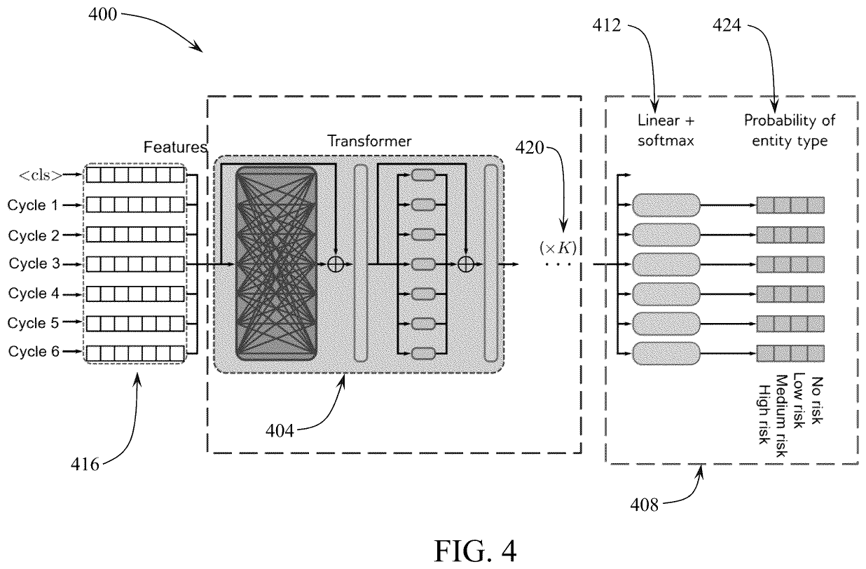

In other embodiments, a model of the present disclosure may be finetuned using a flexible adaptor. For example, FIG. 4 illustrates an example finetunable (FT) model 400 that includes a pretrained model 404 and a flexible adaptor 408 for effecting the finetuning. In this example, the flexible adaptor 408 is independent relative to the pretrained model 404 and can be used to finetune the FT model 400 for any one or more of a variety of downstream tasks. Instead of finetuning an existing module of a pretrained model as described above in section II. B. i, FIG. 4 illustrates a new model architecture, i.e., the flexible adaptor 408, that is set for one or more specific tasks. By effectively compiling the flexible adapter 408 into the original pretrained model 404, finetuning the FT model 400 can be done with more flexibility.

In some embodiments, the flexible adapter 408 includes a linear layer 412. In other embodiments, the flexible adapter 408 includes a layer not illustrated) that is decomposed into the multiplication of lower rank matrices, which involves even fewer changes of parameters. In the example shown in FIG. 4, the pretrained model 404 is an encoder having the transformer architecture shown and that operates on MTS data 416, here, battery cycle data, containing features. The pretrained model 404 provides its output, i.e., raw scores 420, to the linear layer 412 that, in this example, performs a softmax function to classify the raw scores into probabilities 424.

Those skilled in the art will readily appreciate that models disclosed herein, such as models 100, 304, and 400 of FIGS. 1, 3, and 4, respectively, as well as corresponding methods can also be used in other contexts, such as in quality control or capacity test stages of battery production. Other types of data could also be added, such as design or manufacturing data (e.g., image data). The model could then be used to generate scientific designs more efficiently than traditional methods.

The entire contents of the appended claims are incorporated into this Detailed Description section as if originally presented herein.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A computer-implemented method of analyzing battery data to assess health of a battery, the method comprising:
training an artificial intelligence (AI) model using a plurality of multivariate time-series data sets from battery cycling tests, wherein the AI model has a transformer architecture; and
applying the AI model to the battery data so as to assess the health of the battery.

2. The method of claim 1, wherein the transformer architecture is an encoder-only architecture.

3. The method of claim 2, wherein the transformer architecture is further a bidirectional transformer architecture.

4. The method of claim 2, wherein the plurality of multivariate time-series data sets comprises a plurality of parameters, the plurality of parameters comprising at least capacity, energy, time, temperature, voltage, and current.

5. The method of claim 4, wherein training the AI model further comprises:
randomly masking portions of the plurality of multivariate time-series data sets so as to form masked information;
reconstructing the masked information using the AI model to learn contextual information and multivariate interactions within the plurality of multivariate time-series data sets; and
utilizing self-attention mechanisms within the transformer architecture to train the AI model without the need for explicit labeled data.

6. The method of claim 5, wherein applying the AI model comprises estimating the battery's state of charge.

7. The method of claim 5, wherein applying the AI model comprises estimating the battery's state of health.

8. The method of claim 5, wherein applying the AI model comprises estimating the battery's remaining useful life.

9. The method of claim 5, wherein applying the AI model comprises detecting anomalies of the battery.

10. The method of claim 5, wherein applying the AI model comprises finetuning the AI model for a specific downstream task.

11. The method of claim 10, wherein the specific downstream task is one of anomaly detection, life prediction, estimation of the battery's state of charge, and estimation of the battery's state of health.

12. The method of claim 11, wherein finetuning the AI model for a specific downstream task comprises masking an input with a specific mechanism and adjusting only a last subset of blocks of the AI model, while maintaining a plurality of core transformer layers unchanged.

13. The method of claim 11, wherein finetuning the AI model for a specific downstream task comprises using a flexible adaptor independent of the AI model.

14. The method of claim 11, wherein finetuning the AI model for a specific downstream task comprises leveraging the AI model for a zero-shot application.

15. The method of claim 14, wherein leveraging the AI model for a zero-shot application comprises setting a plurality of appropriate masks for an input to directly use the AI model for the specific downstream task.

16. The method of claim 1, wherein the plurality of multivariate time-series data sets from battery cycling tests comprises multiple years of data.

17. The method of claim 1, wherein the AI model is operated on a computational system equipped with one or more GPUs.

18. The method of claim 1, wherein the AI model is deployed on a cloud server.

19. A computer-implemented method of assessing health of a battery, the method comprising:
receiving measured battery data regarding the battery;
inputting the measured battery data into a transformer-based battery-health model that has been trained on historical battery testing data; and
receiving an indication of the health of the battery as an output of the battery-health model.

20. The computer-implemented method of claim 19, wherein the transformer-based battery-health model has been trained in accordance with training of the AI model of claim 1.

21. A machine-readable storage medium containing machine-executable instructions for performing the method of claim 1.

22. A system, comprising:
at least one processor for executing machine-executable instructions; and
a machine-readable storage medium operatively connected to the at least one processor, wherein the machine-readable storage medium containing machine-executable instructions for performing the method of claim 1.

23. The system of claim 22, wherein the system is a battery-testing system.

24. The system of claim 22, wherein the system is a battery-management system.

25. The system of claim 24, wherein the battery-management system is part of a vehicle-control system.
